(19) United States
(12) Patent Application Publication
(10) Pub. No.: US 2026/0160652 A1
(43) Pub. Date: Jun. 11, 2026

(54) ACOUSTIC DEVICE AND METHOD FOR ENHANCED SENSOR DETECTION

(71) Applicant: THE TRUSTEES OF INDIANA UNIVERSITY, Bloomington, IN (US)

(72) Inventors: Feng GUO, Bloomington, IN (US); Zheng AO, Bloomington, IN (US); Xiang LI, Bloomington, IN (US)

(21) Appl. No.: 18/708,059

(22) PCT Filed: Dec. 13, 2022
(86) PCT No.: PCT/US2022/052686

§ 371 Date: May 7, 2024

Related U.S. Application Data
(60) Provisional application No. 63/294,099, filed on Dec. 28, 2021.

(51) Int. Cl. G01N 1/40; G01N 15/01; G01N 15/1031; H10N 30/06; H10N 30/20

(52) U.S. Cl. CPC G01N 1/40; G01N 15/1031; G01N 15/01; H10N 30/06; H10N 30/20

(57) ABSTRACT

A method for enhancing the detection of target particles in a sample includes dispensing the sample over a detection chamber of a sensor. The method also includes transmitting acoustic waves from an acoustic transducer to the sample. The method also includes measuring a detection signal from the sensor to identify the target particles in the sample.

### CROSS-REFERENCE TO RELATED APPLICATIONS

This application claims priority under 35 U.S.C. § 119(e) to U.S. Provisional Application No. 63/294,099, filed Dec. 28, 2021, which is expressly incorporated by reference herein.

### BACKGROUND

Organic electrochemical transistors have been a promising platform in the field of bioelectronics due to advantages such as low-cost, good biocompatibility, and excellent stability when dealing with an aqueous ionic interface. A typical organic electrochemical transistor includes three terminals: the source, the drain, and the gate. A conductive organic material is introduced to connect the source and drain forming the organic channel. An electrolyte medium is used to connect the gate electrode and the organic channel. When compared with other types of thin-film transistors, the presence of the corresponding electrolyte double layer at the gate-electrolyte-channel interface can provide a large gate channel capacitance. The penetration of the ions into the organic channel enable the organic electrochemical transistor to operate at a relatively low gate voltage but with a good signal amplification. The organic channel can be further functionalized by antibodies to increase the specificity by measuring the gate voltage shift caused by antibody-antigen reactions.

### SUMMARY

The present disclosure includes one or more of the features recited in the appended claims and/or the following features which, alone or in any combination, may comprise patentable subject matter.

According to a first aspect of the disclosed embodiments, a method for enhancing the detection of target particles in a sample includes dispensing the sample over a detection chamber of a sensor. The method also includes transmitting acoustic waves from an acoustic transducer to the sample to cause the target particles in the sample to move toward a detection surface of the detection chamber. The method also includes measuring a detection signal from the sensor to identify the target particles in the sample.

In some embodiments of the first aspect, dispensing the sample over a detection chamber of a sensor may include dispensing the sample over a detection chamber of at least one of an electrical sensor, a chemical sensor, an acoustic sensor, and an optical sensor. Measuring a detection signal may include measuring at least one of an electrical signal or other detection signal. The method may also include enhancing the detection signal with the acoustic waves in comparison to a detection signal without the acoustic waves. The detection signal with the acoustic waves may be enhanced at least 2 times in comparison to the detection signal without the acoustic waves. The method may also include transmitting acoustic waves having a frequency within a range of approximately 1 kHz to 900 MHz. The method may also include identifying target particles including at least one of biological cells, extracellular vesicles, organic conjugations, and inorganic particles. The method may also include fabricating an acoustic transducer by depositing electrodes on a piezoelectric substrate. The method may also include coupling acoustic waves into the detection chamber of the sensor.

According to a second aspect of the disclosed embodiments, a system for enhancing the detection of target particles in a sample includes a piezoelectric substrate and an acoustic transducer deposited on the piezoelectric substrate. A sensor is deposited on the piezoelectric substrate. The sensor has a detection chamber. The acoustic transducer is focused on the detection chamber of the sensor to apply acoustic waves to a sample in the detection chamber to cause target particles in the sample to move toward a detection surface of the detection chamber. A detection signal measured in the sensor identifies the target particles in the sample.

In some embodiments of the second aspect, the detection signal may include at least one of a gate voltage and an electrical signal. The sensor may be at least one of an electrical sensor, a chemical sensor, an acoustic sensor, and an optical sensor. The acoustic transducer may enhance a measured gate voltage with the acoustic waves in comparison to a measured gate voltage without the acoustic waves. The acoustic waves may have a frequency within a range of approximately 1 kHz to 900 MHz. The target particles may include at least one of biological cells, extracellular vesicles, organic conjugations, and inorganic particles.

### BRIEF DESCRIPTION OF THE DRAWINGS

The detailed description particularly refers to the accompanying figures in which:

FIG. 1 is a schematic view of a sensing system having an acoustic transducer and a sensor deposited on a piezoelectric substrate;

FIG. 2 is a schematic view of the sensing system having a small volume of a sample deposited in a detection chamber of the sensor;

FIG. 3 is a schematic view of the sensing system transmitting an acoustic wave to cause a reaction between a target particle and a detection surface of the detection chamber;

FIG. 4 is a schematic view of the sensing system having the target particle moved toward the detection surface;

FIG. 5 is a graph of a transfer characteristic after the incubation of an electrolyte droplet sample containing different concentration of E. coli bioparticles;

FIG. 6 is a graph of a comparison of the performance of bioparticle detection with or without acoustic enhancement, wherein the relative change of the gate voltage (AVG) is plotted as a function of bioparticle concentration; and

FIG. 7 is a flowchart of a method for enhancing the detection of the target particle in the sample.

### DETAILED DESCRIPTION

While the concepts of the present disclosure are susceptible to various modifications and alternative forms, specific exemplary embodiments thereof have been shown by way of example in the drawings and will herein be described in detail. It should be understood, however, that there is no intent to limit the concepts of the present disclosure to the particular forms disclosed, but on the contrary, the intention is to cover all modifications, equivalents, and alternatives falling within the spirit and scope of the invention as defined by the appended claims.

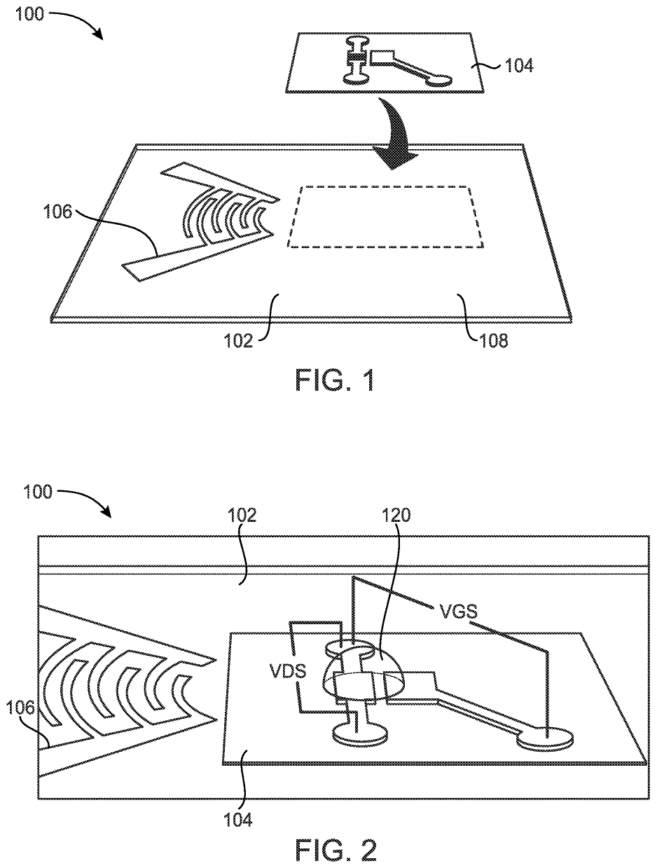

Referring now to FIGS. 1-4, a sensing system 100 includes an acoustic chip 102 and a sensor 104. In some embodiments, the sensing system 100 is a biosensing system. The sensing system 100 may be utilized to enhance the detection of target particles including biological cells, extracellular vesicles, organic conjugations, and/or inorganic particles. The sensor 104 may be any one of an electrical sensor, a chemical sensor, an acoustic sensor, or an optical sensor. In the illustrated embodiment, the sensor 104 is an organic electrochemical transistor. As shown in FIG. 1, the acoustic chip 102 is fabricated with an acoustic transducer 106 deposited on a piezoelectric substrate 108. The sensor 104 is positioned on top of the acoustic chip 102. That is, the sensor 104 is positioned on the piezoelectric substrate 108.

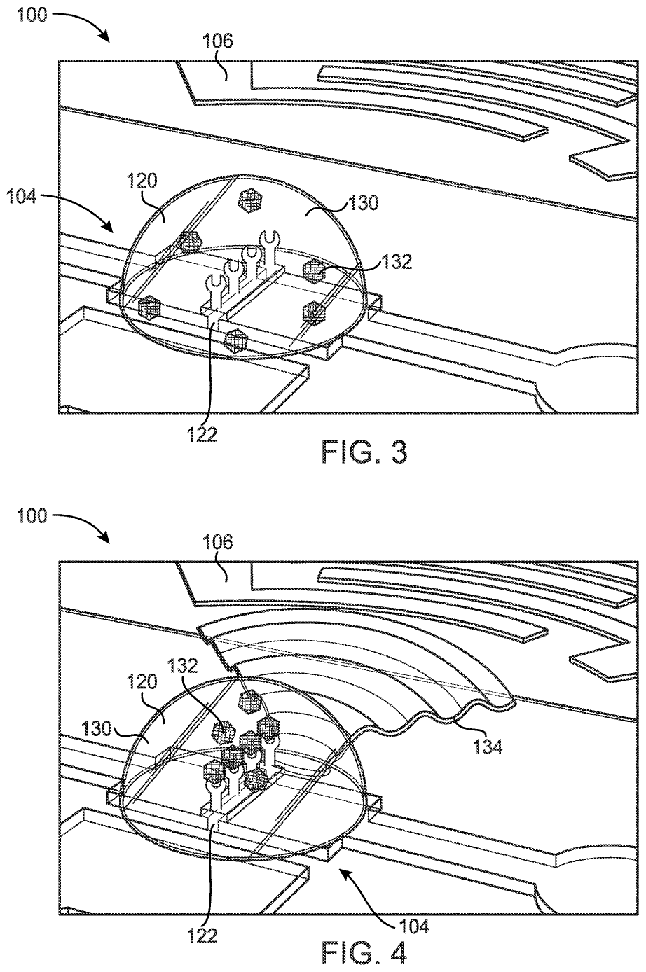

The sensor 104 includes a detection chamber 120 having a detection surface 122 that is positioned in the focal point of the acoustic enrichment. In an exemplary embodiment, the detection chamber 120 is an organic gate and the detection surface 122 includes an electrode. As illustrated in FIG. 2, a sample 130 having a target particle 132, for example, an electrolyte solution having a specific bioparticle, is positioned in the detection chamber 120 and covers the detection surface 122. In an exemplary embodiment, the sample covers an organic channel and a gate electrode. The corresponding gate voltage shift due to the bonding between the sample and the detection surface 122 can be quantified. With the assistance of an acoustic wave 134 (shown in FIG. 4) from the acoustic transducer 106, a reaction is caused between the target particles 132 and the detection surface 122, as illustrated in FIG. 3. The acoustic waves 134 may have a frequency within a range of approximately 1 kHz to 900 MHz. FIG. 4 illustrates the target particles 132 moved toward the detection surface 122 to enhance sensitivity and testing speed of the system 100.

A detection signal is measured in the sensor to identify the target particles in the sample. In some embodiments, the detection signal may include a gate voltage and an electrical signal. In an exemplary embodiment, the acoustic transducer 106 enhances a measured gate voltage with the acoustic waves 134 in comparison to a measured gate voltage without the acoustic waves 134.

The system 100 may be utilized in clinical medicine, the food industry, agriculture, and for environmental protection. Although a variety of sensors such as organic electrochemical transistors have been developed for different practical applications, challenges remain in detecting real-world samples due to high variations such as sample concentration. In an exemplary embodiment, an acoustic sample concentration method enhances the sensitivity of an organic electrochemical transistor. By coupling the acoustic waves 134 into the detection chamber 120 of the organic electrochemical transistor, the target particles (or beads captured with target molecules) are trapped, concentrated, and attached to the detection surface 122. The detection level of bacteria by an acoustically enhanced organic electrochemical transistor may be enhanced by approximately 100 times as that by a conventional organic electrochemical transistor. In some embodiments, the detection is enhanced by more than two times. In some embodiments, the detection is enhanced between 2 and 200 times. This system 100 is versatile, and can be coupled onto various chemical bonding-based sensors such as chemical sensors, electrical sensors, and optical sensors. The system may be used to detect biological cells, extracellular vesicles, organic conjugations, inorganic particles, and various molecules that bond to beads for basic research and practical applications.

To meet real-world analytical challenges, organic electrochemical transistor devices must overcome barriers such as small volume sample and a more efficient selective trapping mechanism at the sensing interface. The system 100 increases the detecting performance of organic electrochemical transistors. The system 100 may be fabricated with interdigital transducers deposited on piezoelectric substrates such as lithium niobate (LiNbO3). When applying radio-frequency signals at a resonant frequency of the acoustic concentration device, standing surface acoustic waves may be generated and radiated away from the interdigital transducers. The propagation of the standing surface acoustic waves through a liquid domain, such as a droplet of electrolyte medium, induces an acoustic streaming flow within the fluid. By precise positioning of the acoustic chip 102, the bioparticles within the fluid body are concentrated into a focal point (i.e. the sensing interface at the organic electrochemical transistor) thus enabling localized enrichment via a non-invasive, energy efficient and easy-to-implement method.

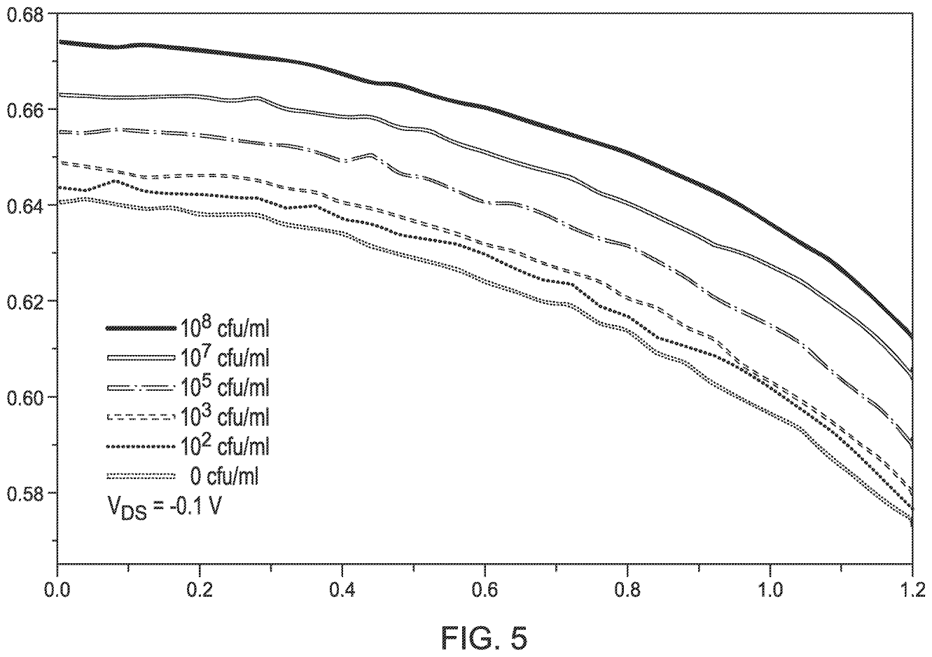

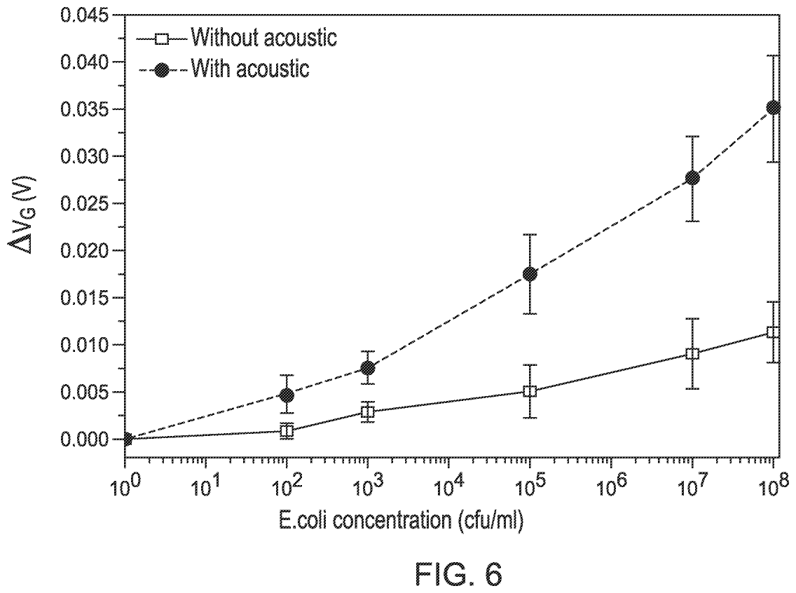

FIG. 5 illustrates the acoustic sample concentration method used for enhancing the detection of E. coli cells using an organic electrochemical transistor. Due to the acoustic concentration of E. coli cells, the gate voltage shift of the organic electrochemical transistor was increased by 2 folds at the higher concentration level and 4.7 folds at the lower level thus greatly decreasing the detection limit of the system, as illustrated in FIG. 6.

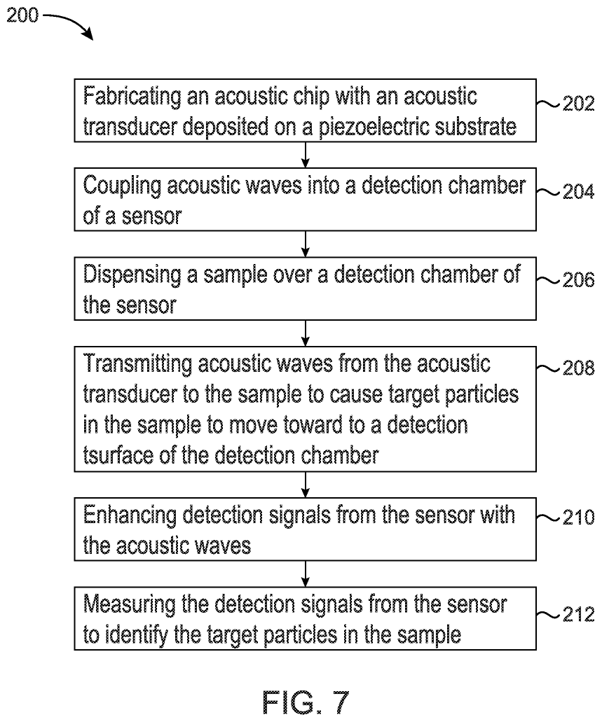

FIG. 7 is a flowchart of a method 200 for enhancing the detection of the target particle in the sample. At block 202, the acoustic chip 102 is fabricated with the acoustic transducer 106 deposited on the piezoelectric substrate 108. In some embodiments, the acoustic transducer 106 is fabricated by depositing electrodes on the piezoelectric substrate 108. The sensor 104 is also deposited on the piezoelectric substrate 108. At block 204, the 134 acoustic waves are coupled into the detection chamber 120 of the sensor 104. At block 206, the sample is dispensed over the detection chamber 120 of the sensor 104. At block 208, the acoustic waves 134 are transmitted from the acoustic transducer 106 to the sample to cause target particles in the sample to move toward the detection surface 122 of the detection chamber 120. In some embodiments, the method 200 includes coupling the acoustic waves 134 into the detection chamber 120 of the sensor 102. In some embodiments, the acoustic waves 134 have a frequency within a range of approximately 1 kHz to 900 MHz.

At block 210, a detection signal from the sensor 104 is enhanced with the acoustic waves 134. For example, the detection signal with the acoustic waves 134 is enhanced in comparison to a detection signal without the acoustic waves 134. In an exemplary embodiment, the detection signal with the acoustic waves 134 is enhanced at least 2 times in comparison to the detection signal without the acoustic waves 134. At block 212 the detection signal from the sensor 104 is measured to identify the target particles 132 in the sample. The detection signal may be a gate voltage or an electrical signal. The target particles 132 may include at least one of biological cells, extracellular vesicles, organic conjugations, and/or inorganic particles.

Any theory, mechanism of operation, proof, or finding stated herein is meant to further enhance understanding of principles of the present disclosure and is not intended to make the present disclosure in any way dependent upon such theory, mechanism of operation, illustrative embodiment, proof, or finding. It should be understood that while the use of the word preferable, preferably or preferred in the description above indicates that the feature so described can be more desirable, it nonetheless cannot be necessary and embodiments lacking the same can be contemplated as within the scope of the disclosure, that scope being defined by the claims that follow.

In reading the claims it is intended that when words such as “a,” “an,” “at least one,” “at least a portion” are used there is no intention to limit the claim to only one item unless specifically stated to the contrary in the claim. When the language “at least a portion” and/or “a portion” is used the item can include a portion and/or the entire item unless specifically stated to the contrary.

It should be understood that only selected embodiments have been shown and described and that all possible alternatives, modifications, aspects, combinations, principles, variations, and equivalents that come within the spirit of the disclosure as defined herein or by any of the following claims are desired to be protected. While embodiments of the disclosure have been illustrated and described in detail in the drawings and foregoing description, the same are to be considered as illustrative and not intended to be exhaustive or to limit the disclosure to the precise forms disclosed. Additional alternatives, modifications and variations can be apparent to those skilled in the art. Also, while multiple inventive aspects and principles can have been presented, they need not be utilized in combination, and many combinations of aspects and principles are possible in light of the various embodiments provided above.

1. A method for enhancing the detection of target particles in a sample, the method comprising:
dispensing the sample over a detection chamber of a sensor,
transmitting acoustic waves from an acoustic transducer to the sample to cause the target particles in the sample to move toward a detection surface of the detection chamber, and
measuring a detection signal from the sensor to identify the target particles in the sample.

2. The method of claim 1, wherein dispensing the sample over a detection chamber of a sensor further comprises dispensing the sample over a detection chamber of at least one of an electrical sensor, a chemical sensor, an acoustic sensor, and an optical sensor.

3. The method of claim 1, wherein measuring a detection signal further comprises measuring at least one of an electrical signal or other detection signals.

4. The method of claim 1, further comprising enhancing the detection signal with the acoustic waves in comparison to a detection signal without the acoustic waves.

5. The method of claim 4, wherein the detection signal with the acoustic waves is enhanced at least 2 times in comparison to the detection signal without the acoustic waves.

6. The method of claim 1, further comprising transmitting acoustic waves having a frequency within a range of approximately 1 kHz to 900 MHz.

7. The method of claim 1 further comprising identifying target particles including at least one of biological cells, extracellular vesicles, organic conjugations, and inorganic particles.

8. The method of claim 1, further comprising fabricating an acoustic transducer by depositing electrodes on a piezoelectric substrate.

9. The method of claim 1, further comprising coupling acoustic waves into the detection chamber of the sensor.

10. A system for enhancing the detection of target particles in a sample, the system comprising:
a piezoelectric substrate,
an acoustic transducer deposited on the piezoelectric substrate, and
a sensor deposited on the piezoelectric substrate, the sensor having a detection chamber,
wherein the acoustic transducer is focused on the detection chamber of the sensor to apply acoustic waves to a sample in the detection chamber to cause target particles in the sample to move toward a detection surface of the detection chamber, and
wherein a detection signal measured in the sensor identifies the target particles in the sample.

11. The system of claim 10, wherein the detection signal includes at least one of a gate voltage and an electrical signal.

12. The system of claim 10 wherein the sensor is at least one of an electrical sensor, a chemical sensor, an acoustic sensor, and an optical sensor.

13. The system of claim 10, wherein the acoustic transducer enhances a measured gate voltage with the acoustic waves in comparison to a measured gate voltage without the acoustic waves.

14. The system of claim 10, wherein the acoustic waves have a frequency within a range of approximately 1 kHz to 900 MHz.

15. The system of claim 10, wherein the target particles include at least one of biological cells, extracellular vesicles, organic conjugations, and inorganic particles.
